(19) United States
(12) Patent Application Publication
(10) Pub. No.: US 2026/0040959 A1
(43) Pub. Date: Feb. 5, 2026

(54) CHIP ON LEAD DEVICE AND MANUFACTURING METHOD

(71) Applicant: Texas Instruments Incorporated, Dallas, TX (US)

(72) Inventor: Anindya Poddar, Sunnyvale, CA (US)

(21) Appl. No.: 18/790,494

(22) Filed: Jul. 31, 2024

(51) Int. Cl. H01L 23/495; H01L 21/3065; H01L 21/48; H01L 23/00; H05K 1/18

(52) U.S. Cl. CPC H01L 23/49548; H01L 21/3065; H01L 21/4842; H01L 24/48; H01L 2224/48245; H01L 2224/48451; H01L 2224/48456; H01L 2924/1815; H05K 1/181; H05K 2201/09372; H05K 2201/10439

(57) ABSTRACT

An electronic device includes a non-conductive die attach film on a side of a conductive lead, a semiconductor die having a first side and a lateral side, the first side on the non-conductive die attach film, and the lateral side including striations, and a package structure enclosing the semiconductor die and a portion of the conductive lead. A method includes singulating portions of a non-conductive die attach film on a carrier, attaching a backside of a wafer to the singulated portions of the non-conductive die attach film, and singulating semiconductor dies of the wafer while the backside of the wafer is attached to the singulated portions of the non-conductive die attach film.

### BACKGROUND

Reduced electronic device package sizes is important for many applications, and often inhibits the ability to provide a dedicated die attach pad (DAP) for supporting a semiconductor die. Chip on lead (COL) designs have a die mounted to a lead and may use nonconductive die attach film (DAF) to isolate the die from a voltage signal of the attached lead. However, silicon particles remaining in or alongside the die attach film from a die or DAF singulation process can cause shorts or leakage between the lead and the attached die.

### SUMMARY

In one aspect, an electronic device includes a non-conductive die attach film on a side of a conductive lead, a semiconductor die having a first side and a lateral side, the first side on the non-conductive die attach film, and the lateral side including striations, and a package structure enclosing the semiconductor die and a portion of the conductive lead.

In another aspect, a system includes a circuit board and an electronic device with a conductive lead connected to a conductive feature of the circuit board, a non-conductive die attach film on a side of the conductive lead, a semiconductor die having a first side and a lateral side, the first side on the non-conductive die attach film, and the lateral side including striations, and a package structure enclosing the semiconductor die and a portion of the conductive lead.

In a further aspect, a method includes singulating portions of a non-conductive die attach film on a carrier, attaching a backside of a wafer to the singulated portions of the non-conductive die attach film, and singulating semiconductor dies of the wafer while the backside of the wafer is attached to the singulated portions of the non-conductive die attach film.

### BRIEF DESCRIPTION OF THE DRAWINGS

FIG. 1 is a partial sectional side elevation view of a chip on lead electronic device including a preformed die attach adhesive taken along line 1-1 of FIG. 1A.

FIG. 1A is a top plan view of the electronic device of FIG. 1.

FIG. 2 is a flow diagram of a method of making an electronic device.

FIGS. 3-16 are partial sectional side elevation views of the electronic device of FIGS. 1 and 1A undergoing fabrication processing according to the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means+/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for case of description in connection with a particular drawing, where such are not to be construed as limiting with respect to the claims. Various structures and methods of the present disclosure may be beneficially applied to an electronic device or apparatus such as an integrated circuit and to manufacturing electronic devices. While such examples may be expected to provide various improvements, no particular result is a requirement of the present disclosure unless explicitly recited in a particular claim.

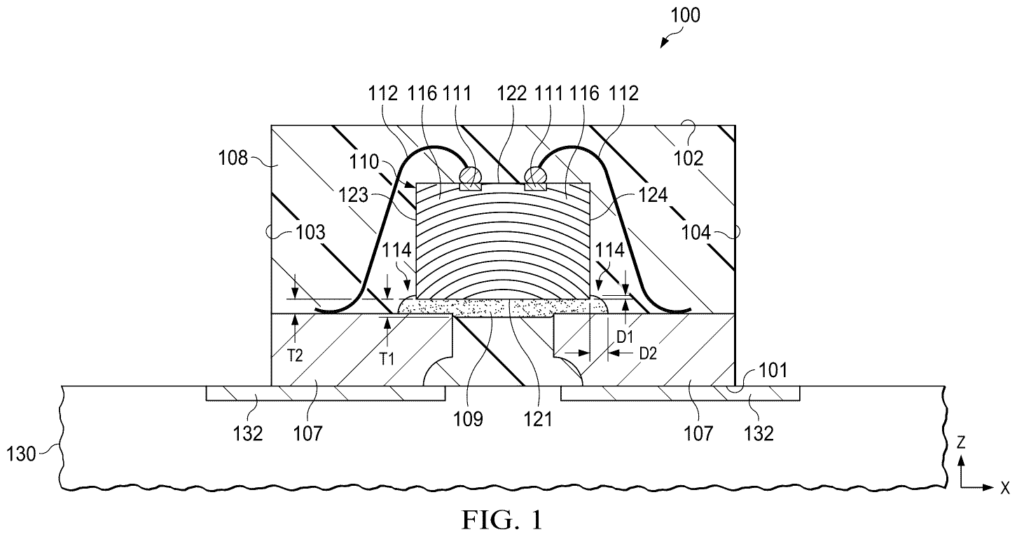

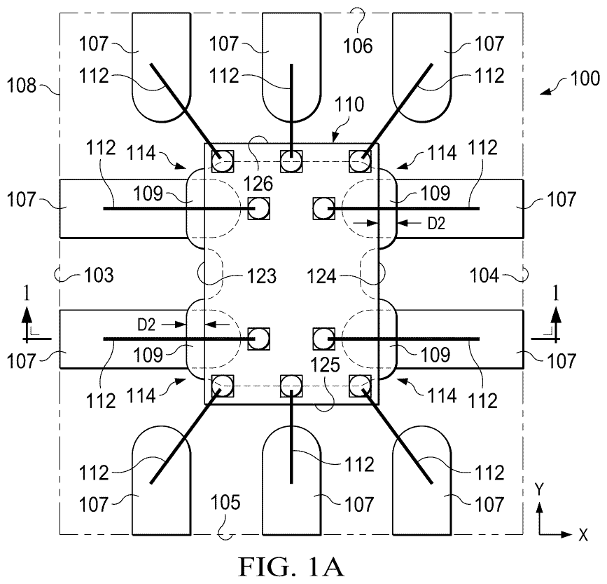

FIGS. 1 and 1A show an electronic device 100, which can be an integrated circuit (IC) with two or more electronic components, or any electronic device with one or more electronic components. The electronic device 100 is shown in an example three-dimensional space with a first direction X, a perpendicular (orthogonal) second direction Y (FIG. 1A), and a third direction Z (FIG. 1) that is perpendicular (orthogonal) to the first and second directions X and Y. Structures or features along any two of these directions are orthogonal to one another. The electronic device 100 has opposite first and second (e.g., bottom and top) sides 101 and 102, respectively, which are spaced apart from one another along the third direction Z in the illustrated position in FIG. 1. The electronic device 100 also has laterally opposite third and fourth sides 103 and 104 that are spaced apart from one another along the first direction X, and fifth and sixth sides 105 and 106 (FIG. 1A) that are spaced apart from one another along the second direction Y in the illustrated position.

The electronic device 100 includes conductive leads 107 and a package structure 108 that encloses portions of the leads 107 and non-conductive die attach film 109 that attaches a semiconductor die 110 to some of the leads 107. The leads 107 in one example are or include conductive metal, such as copper, aluminum, etc. The non-conductive die attach film 109 can be any low electrical conductivity adhesive material that attaches the semiconductor die 110 to one or more conductive leads 107. The package structure 108 in one example is a generally rectangular plastic molded structure and defines approximately planar bottom, top and lateral sides 102-106, although not a requirement of all possible implementations. The illustrated example has the semiconductor die 110 attached to portions of four conductive leads 107. In other examples, the semiconductor die 110 can be attached to more or fewer leads 107 or portions thereof using non-conductive die attach film 109.

The example electronic device 100 has a single semiconductor die 110. Other examples can include more than one semiconductor die 110. The semiconductor die 110 has a bottom or first side 121 (FIG. 1), a top or second side 122 (FIG. 1) and lateral sides 123, 124 (FIG. 1), 125, and 126 (FIG. 1A). The bottom or first side 121 of the semiconductor die 110 extends at least partially on the top side of the non-conductive die attach film 109. The first side 121 of the semiconductor die 110 is a die back side, and the second side 122 is a die front side with conductive features 111 (FIG. 1) such as copper or aluminum bond pads, studs, pillars, or other conductive terminals. At least some of the conductive features 111 are electrically connected to respective ones or groups of the conductive leads 107 in one example. The conductive features 111 provide electrical connections to one or more components and/or circuits in the semiconductor die 110, such as resistors, transistors, diodes, capacitors, inductors, etc. (not shown). The package structure 108 encloses the semiconductor die 110 and portions of the respective conductive leads 107.

The electronic device 100 in one example includes bond wires 112 (e.g., conductive aluminum, copper, etc.) connected between respective conductive leads 107 and conductive features 111 of the semiconductor die 110. The conductive features 111 and bond wires 112 provide electrical connections between the component(s) or circuit(s) of the semiconductor die 110 and a host circuit board or system in which the electronic device 100 is installed. In other examples, different electrical interconnection types and forms can be provided, such as flip-chip attachments, substrates, clips, etc. (not shown). In the illustrated example, the two laterally opposite leads 107 shown in the section view of FIG. 1 are each connected by a bond wire 112 to a respective one of the conductive features 111 of the top side 122 of the semiconductor die 110 and the device includes several interconnections of conductive die features 111 to respective ones of the leads 107 as shown in FIG. 1A.

The non-conductive die attach film 109 extends on a portion of the top side of the attached conductive leads 107 and on a portion of the bottom or first side 121 of the semiconductor die 110. A portion of the non-conductive die attach film 109 can extend on a portion of one or more lateral sides of the conductive leads 107, for example, as shown in FIG. 1, although not a requirement of all possible implementations. The non-conductive die attach film 109 has upwardly extending corner portions 114 that extend on portions of the two opposite the lateral sides 123 and 124 of the semiconductor die 110 above a plane of the first side 121 of the semiconductor die 110 by a first distance D1 (FIG. 1). The corner portions 114 of the non-conductive die attach film 109 also extend laterally outward on the respective top sides of the conductive leads 107 by a second distance D2 past planes of the opposite lateral sides 123 and 124 along the first direction X in the illustrated orientation of FIGS. 1 and 1A. In other implementations, the non-conductive die attach film 109 can have a single corner portion that extends at least partially on one lateral side of the semiconductor die 110, for example, where the semiconductor die 110 is attached by non-conductive die attach film 109 to a single one of the conductive leads 107.

The non-conductive die attach film 109 has a portion that does not engage an underlying lead 107 with a first thickness T1 along the third direction Z, for example, between the laterally spaced conductive leads 107 as shown in FIG. 1. The non-conductive die attach film 109 has a second portion that extends along the third direction Z between a portion of the top side of a conductive lead 107 and the first side 121 of the semiconductor die 110 and has a smaller second thickness T2 as shown in FIG. 1. In one example, the difference in the thicknesses T1 and T2, the upward extension by the first distance D1, and the laterally outward extension of the non-conductive die attach film 109 by the second distance D2 at least partially result from compressive downward force applied to the semiconductor die 110 during attachment to the leads 107 in manufacturing of the electronic device 100.

In addition, as shown in FIG. 1, one, some or all of the lateral sides 123-126 of the semiconductor die 110 include striations 116, such as scalloped surfaces or other striations caused by a plasma etching process used to singulate the semiconductor die 110 from a starting wafer. The striations 116 in the example of FIG. 1 have curved features that curve downward toward the first (e.g., bottom) side 121 of the semiconductor die 110 near the lateral corners thereof. In other examples, the striations 116 can have other visually or optically discernible shapes including straight lines, curved lines, curvilinear lines or combinations thereof formed as colorations and/or surface features (e.g., raised and/or indented), surface discontinuities, etc.

The electronic device 100 is shown in FIG. 1 in a system having a circuit board 130 with one or more conductive features 132, such as conductive metal pads. The electronic device 100 in this example has one or more of the conductive leads 107 connected to respective ones of the conductive feature 132 of the circuit board 130, for example, by solder connections to attach the device 100 to the circuit board and to form one or more electrical connections between one or more components and/or circuits of the semiconductor die 110 and a component or circuit of the circuit board 130.

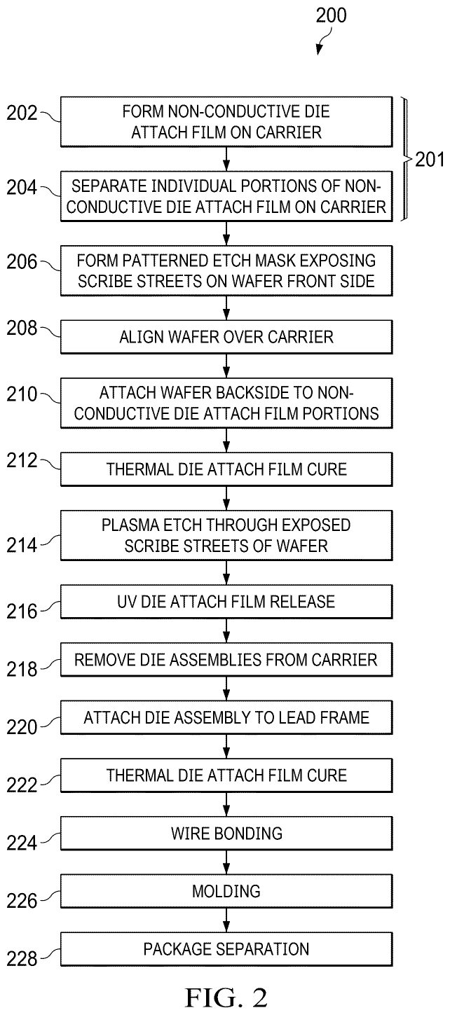

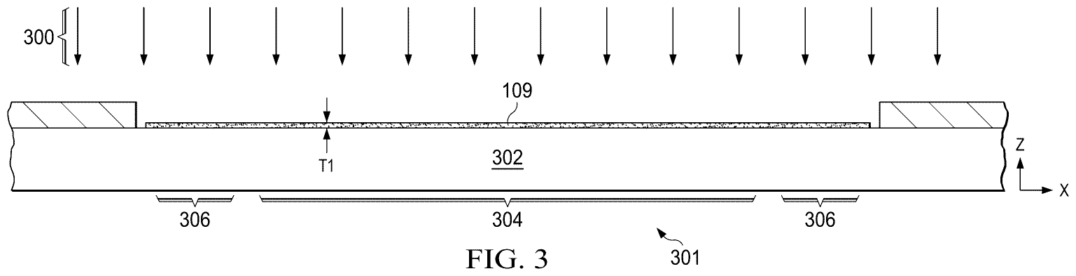

FIG. 2 shows a method 200 of making an electronic device and FIGS. 3-16 show the example electronic device 100 of FIGS. 1 and 1A undergoing fabrication processing according to an implementation of the method 200. The method 200 includes singulating portions of a non-conductive die attach film 109 at 201 in FIG. 2. In one example, the die attach film singulation at 201 includes forming a non-conductive die attach film 109 on a carrier at 202 and die attach film singulation at 204 in FIG. 2. FIG. 3 shows one example, in which a material formation process 300 is performed that forms the non-conductive die attach film 109 on a carrier 301, such as a ring frame. In one example, the carrier 301 includes a carrier tape structure 302, such as a dicing tape installed on the ring frame with a flat or approximately planar top surface on which the non-conductive die attach film 109 is formed at 202. In one example, the process 300 is a lamination process that includes placement and rolling of a layer of non-conductive die attach film 109 on a top surface or side of a tape 302 of the carrier 301. In another example, another material formation process can be used. In the illustrated example, the carrier tape 302 has a prospective wafer portion 304 and one or more peripheral portions 306 laterally spaced apart from the prospective wafer portion 304 as shown in FIG. 3. The process 300 in one example forms the non-conductive die attach film 109 in the prospective wafer portion 304 and also in at least part of the peripheral portions 306, although not a requirement of all possible implementations.

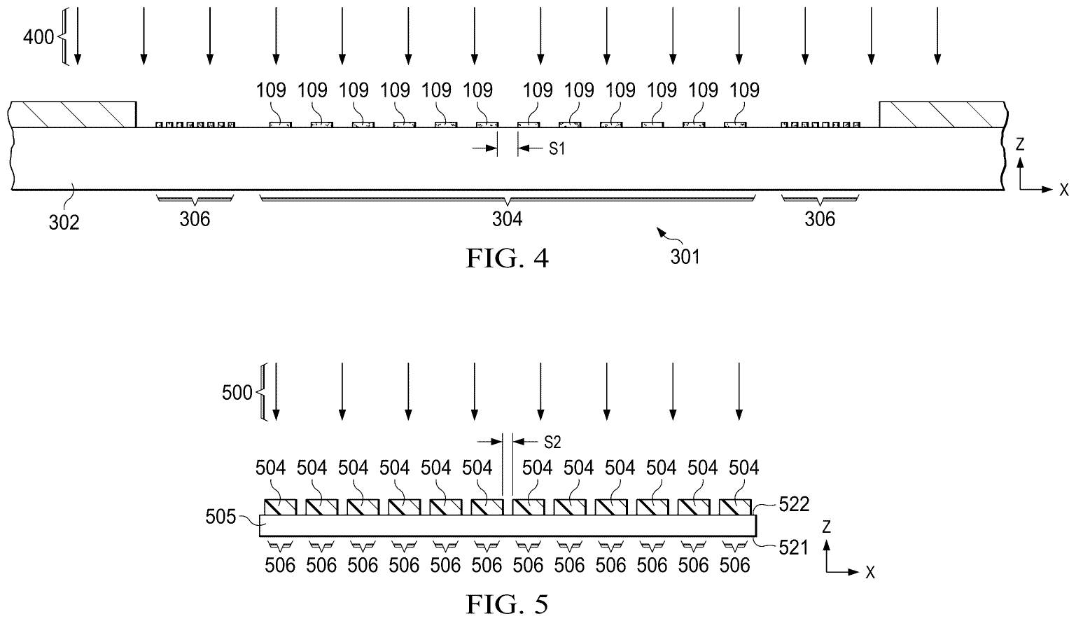

The illustrated example continues with die attach film singulation (e.g., DAF singulation) at 204 in FIG. 2. FIG. 4 shows one example, in which a die attach film singulation or separation process 400 is performed that singulates individual portions of the non-conductive die attach film 109 to separate the portions from one another on the carrier tape 302. The DAF singulation process 400 creates a pattern of separated portions of the non-conductive die attach film 109 in the prospective wafer portion 304, each corresponding to a prospective die area of a wafer to be installed. In the illustrated example, the process 400 also creates a visually or optically discernible pattern of the die attach film 109 in the peripheral portion 306 laterally outward from the patterned portions in the prospective wafer portion 304 as shown in FIG. 4. This can facilitate camera or other optics-based alignment during attachment of a wafer. In another example, the patterned portions in the peripheral portion 306 can be omitted. Any suitable process 400 can be used that separates individual portions of the non-conductive die attach film 109 to separate the portions from one another on the carrier tape 302. In one example, the process 400 is a laser ablation or laser dicing process that uses a laser (not shown) to selectively remove portions of the non-conductive die attach film 109 and leave separated portions that correspond to prospective die areas of a wafer to be subsequently attached. In another example, the process 400 is a mechanical cutting process using a dicing blade (not shown) to selectively remove portions of the non-conductive die attach film 109 between the desired separated portions. These or other types of separation process 400 can be used alone or in combination to form the non-conductive die attach film portions 109 in the prospective wafer portion 304 alone or in further combination with a visually or optically perceptible pattern in the peripheral portion 306 on the top side of the carrier tape 302.

The method 200 in FIG. 2 also includes forming a patterned etch mask at 206 on a front or active side of a wafer. FIG. 5 shows one example, in which a mask formation process 500 is performed that deposits or otherwise forms a mask layer on a wafer 505 and patterns the mask layer to expose scribe street portions on the wafer front side and leave mask portions 504 that cover respective active portions of the front side. The wafer 505 has a first side 521 (e.g., a back or bottom side) and an opposite second side 522 (e.g., a front side or top side). The second side 522 includes bond pads or other conductive features or terminals (not shown in FIG. 5) that provide electrical connection to one or more components are circuits in each of a number of prospective die areas 506 of the wafer 505. In one implementation, the prospective die areas 506 are disposed in rows and columns along the second side 522 of the wafer 505 and the exposed scribe street portions of the second wafer side 522 extend along approximately parallel directions between adjacent prospective die areas 506. Any suitable mask formation and patterning process 500 can be used, and any suitable etch mask material 504 can be used that allows selective etching of the exposed areas to facilitate subsequent die separation as described further below. The mask formation and patterning at 206 and FIG. 2 is done before the wafer 505 is attached to the singulated portions of the non-conductive die attach film 109 to facilitate lower production costs compared to mask formation during electronic device packaging. The process 500 can be performed as part of a standard wafer processing operation before or after any wafer probe testing of a given fabrication process.

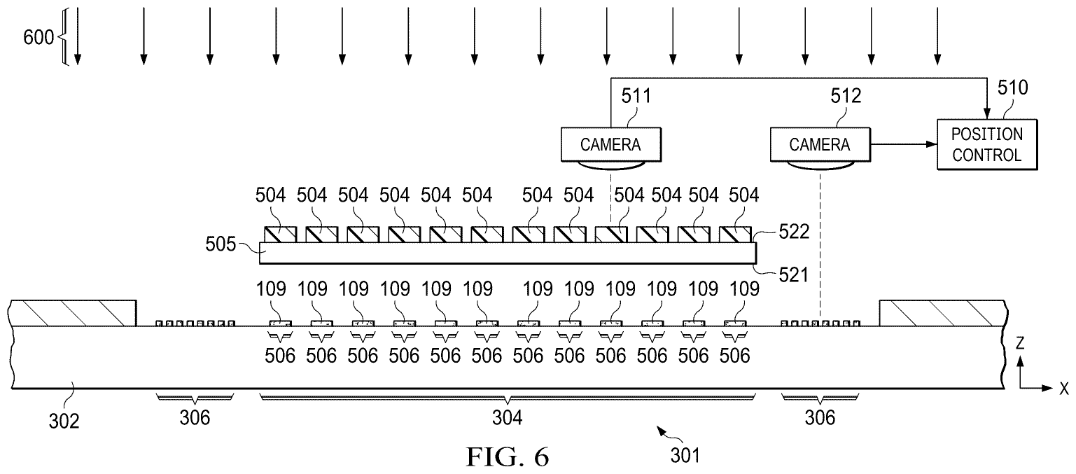

At 208 in FIG. 2, the method 200 in one example includes aligning the wafer 505 over the carrier structure 301. FIG. 6 shows one example, in which a camera assisted alignment process 600 is performed, for example, using an automated position controller 510 with one or more cameras 511 and 512 to align the wafer 505 with the patterned etch mask portions 504 relative to the patterned die attach portions 109 on the top side of the carrier tape 302 prior to a wafer attachment on the die attach film portions 109. In the illustrated example, a first camera 511 locates the position of the wafer 505 in first and second directions (e.g., the illustrated X direction and an orthogonal second direction Y, not shown in FIG. 6), for example, by viewing optically discernible features such as the patterned features of the etch mask 504 on the top side 522 of the wafer 505. In this or another implementation, one or more infrared optical cameras can be used to facilitate alignment of the wafer 505 with respect to the position of the carrier tape 302 and the patterned non-conductive die attach film portions 109. A second camera 512 locates the position of the tape carrier 302 in the X and Y directions, for example, by viewing the optically discernible patterned die attach film material in the peripheral portion 306 of the top side of the carrier tape 302. In another example, the process 600 aligns the prospective die areas 506 of the wafer 505 with respective singulated portions of the non-conductive die attach film 109 by optically aligning the wafer 505 with respect to a pattern of the non-conductive die attach film 109 on the carrier 302.

The position controller 510 adjusts the position of the wafer 505 in the X and/or Y directions to provide a desired alignment to ensure that the prospective die areas 506 of the wafer are adequately aligned to corresponding ones of the patterned die attach film portions 109. The process 600 aligns the prospective die areas 506 of the wafer 505 with respective singulated portions of the non-conductive die attach film 109 before the wafer 504 is attached to the non-conductive die attach film 109.

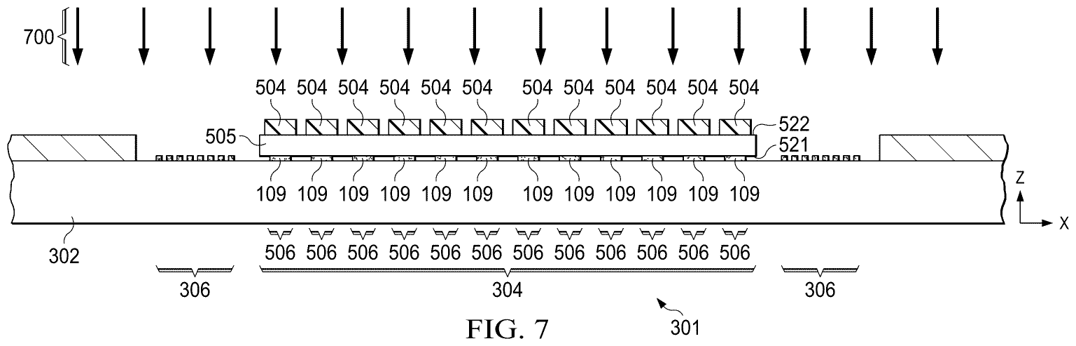

At 210 in FIG. 2, the wafer backside is attached to the non-conductive die attach film portions 109. FIG. 7 shows one example, in which an attachment process 700 is performed that attaches the backside 521 of the wafer 505 to the singulated portions of the non-conductive die attach film 109. In one implementation, the automated position controller 510 of FIG. 6 translates the wafer 505 downward along the third direction Z in FIG. 7 to engage the second side 521 of the wafer 505 to the tops of the singulated portions of the non-conductive die attach film 109.

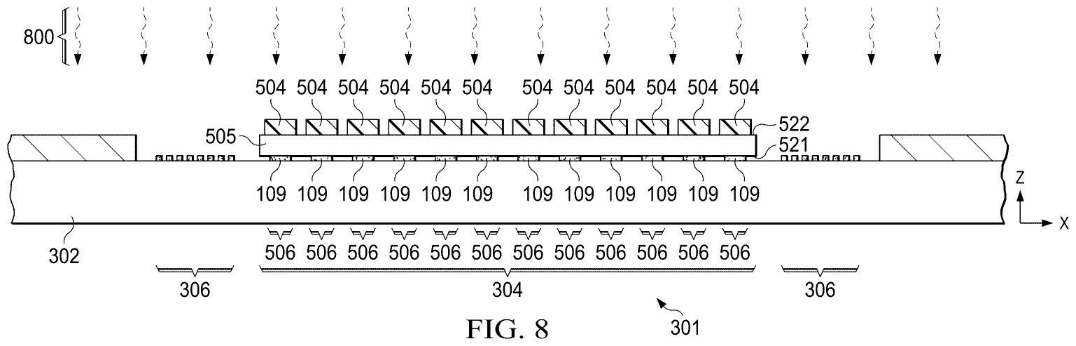

In one implementation, a die attach film curing process is performed at 212 in FIG. 2. FIG. 8 shows one example, in which a thermal adhesive curing process 800 is performed that cures the patterned or singulated portions of the non-conductive die attach film 109 to facilitate adhesion of the top portions of the die attach film 109 to the respective portions of the first side 521 of the wafer 505.

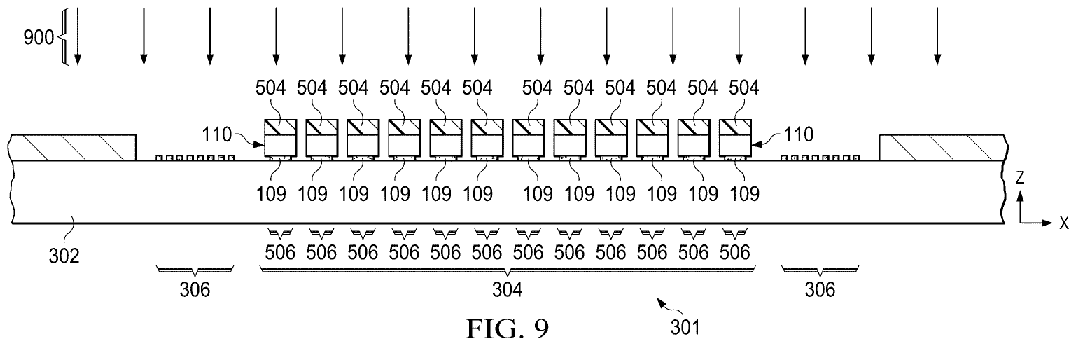

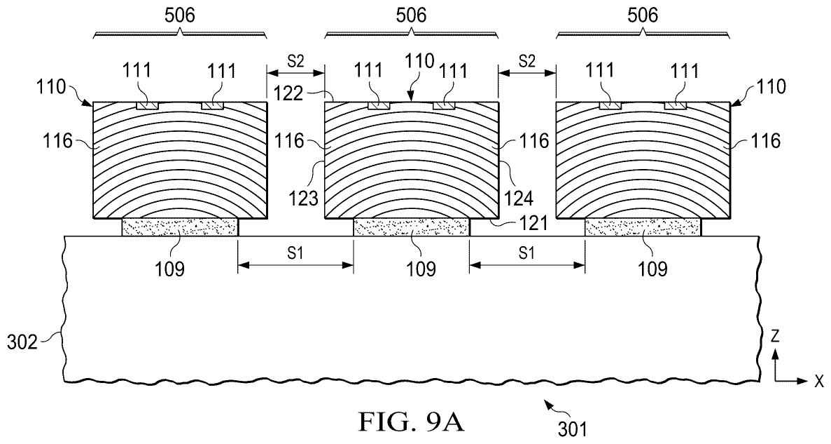

The method 200 in FIG. 2 continues at 214 with die singulation while the backside 521 of the wafer 505 is attached to the singulated portions of the non-conductive die attach film 109. FIG. 9 shows one example, in which a die separation or singulation process 900 is performed that singulates semiconductor dies 110 of the wafer 505 to separate the individual singulated semiconductor dies 110 from the starting wafer structure 505. In one example, the die singulation process 900 is an etch process that separates the semiconductor dies 110 from the wafer 505 with backsides 521 of the semiconductor dies 110 attached to respective singulated portions of the non-conductive die attach film 109. Any suitable etch process can be used that selectively etches the silicon of the wafer 505 in the exposed scribe street portions between the prospective die areas 506. In one implementation, the etch process 900 is a plasma etch process.

FIG. 9A shows a partial view of singulated semiconductor dies 110 after removal of the etch mask 504, with the second or front side 122 including the exposed top sides of the conductive features 111 (e.g., bond pads). FIG. 9A illustrates example spacings including a first spacing distance S1 between adjacent patterned portions of the non-conductive die attach film 109, and a second spacing distance S2 between adjacent separated semiconductor dies 110. In one example, the scribe street openings in the patterned etch mask 504 are approximately 10 μm wide (e.g., S2 in FIG. 9A). Any suitable etch mask opening dimensions can be used by which the plasma etch process 900 or other etch process provides full separation of the individual singulated semiconductor dies 110 from one another and from the starting wafer structure 505. The etch process 900, moreover, need not be optimized or extended with respect to the die attach film 109 because the non-conductive die attach film 109 has been previously patterned.

The example etch process 900 mitigates or avoids cracking of the silicon material of the wafer 505 and the singulated semiconductor dies 110, particularly compared to saw blade dicing and/or laser (e.g., stealth) dicing. The reduction or elimination of cracked silicon particles facilitates electrical isolation of the singulated semiconductor dies 110 from electrically active conductive leads to which the semiconductor die 110 may be subsequently attached, for example, in a compact chip on lead (COL) packaged electronic device 100. In the illustrated example, moreover, the etched openings or spacing S2 (FIG. 9A) between the adjacent separated semiconductor dies 110 in one example is less than the patterned openings S1 in the separated non-conductive die attach film portions 109 as shown in FIG. 9, although not a requirement of all possible implementations. In the illustrated example, the spacing S1 between the patterned portions of the non-conductive die attach film 109 is controlled by the die attach film singulation process (e.g., at 204 in FIG. 2), and the spacing S2 between the adjacent separated semiconductor dies 110 is controlled by the patterning of the etch mask (206 in FIG. 2) and the etch process 900 (at 214 in FIG. 2).

As discussed above in connection with FIGS. 1 and 1A, moreover, the etch process 900 in one example creates striations 116 on one, some or all of the lateral sides 123-126 of the semiconductor die 110, such as scalloped surfaces or other striations caused by the example plasma etching process 900 used to singulate the semiconductor die 110 from the wafer 505. The example striations 116 include curved features that curve downward toward the first (e.g., back or bottom) sides 121 of the semiconductor dies 110 near the lateral corners thereof as shown in FIG. 9A, although curve shapes are not required of all possible implementations and other examples may include different visually or optically discernible shapes such as straight lines, curved lines, curvilinear lines or combinations thereof formed as colorations and/or surface features (e.g., raised and/or indented), surface discontinuities, etc.

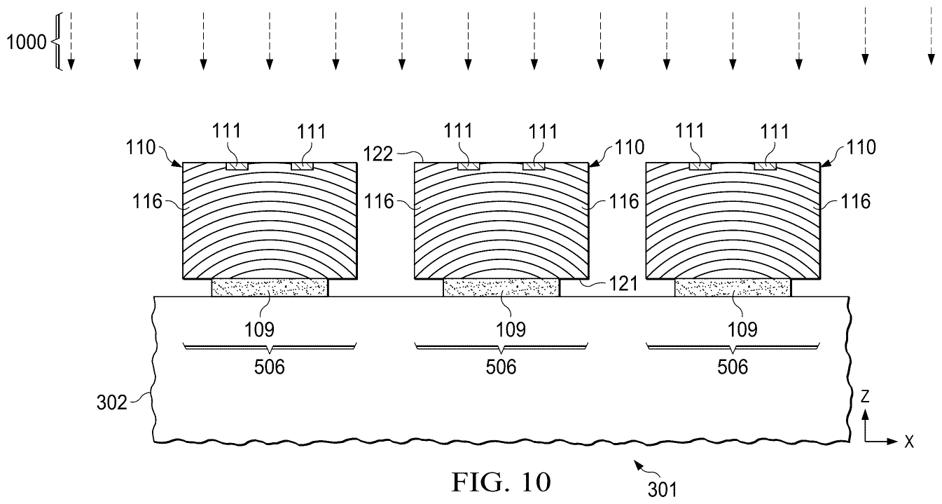

The method 200 continues at 216 in one example with die attach film release, for example, by ultraviolet (UV) exposure. In another implementation, no separate release processing is performed, or a different type or form of release process can be used (e.g., thermal). FIG. 10 shows one example, in which an ultraviolet exposure process 1000 is performed that helps to release the adhesion between the bottom sides of the non-conductive die attach film portions 109 and the top side of the carrier tape 302. This release processing at 216 can facilitate subsequent removal of the individual die assemblies including the separated semiconductor die 110 and the attached patterned portion of the non-conductive die attach film 109, for example, using pick and place equipment (not shown).

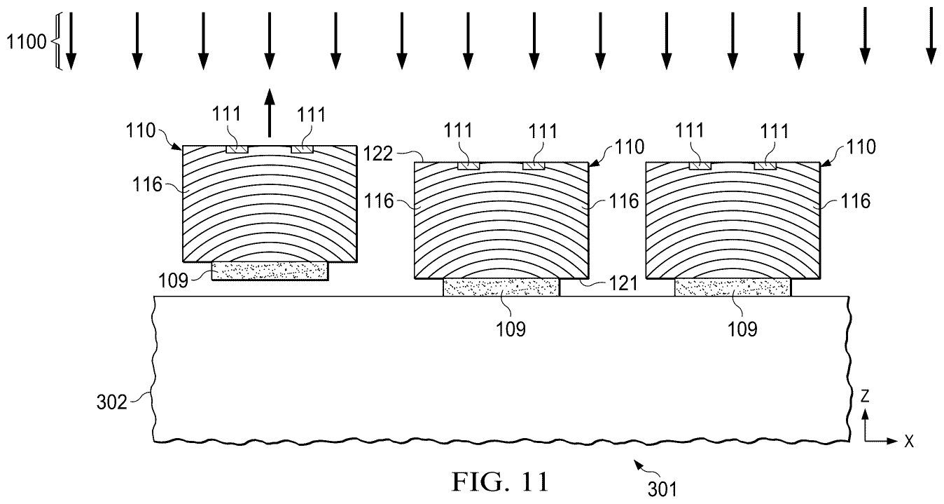

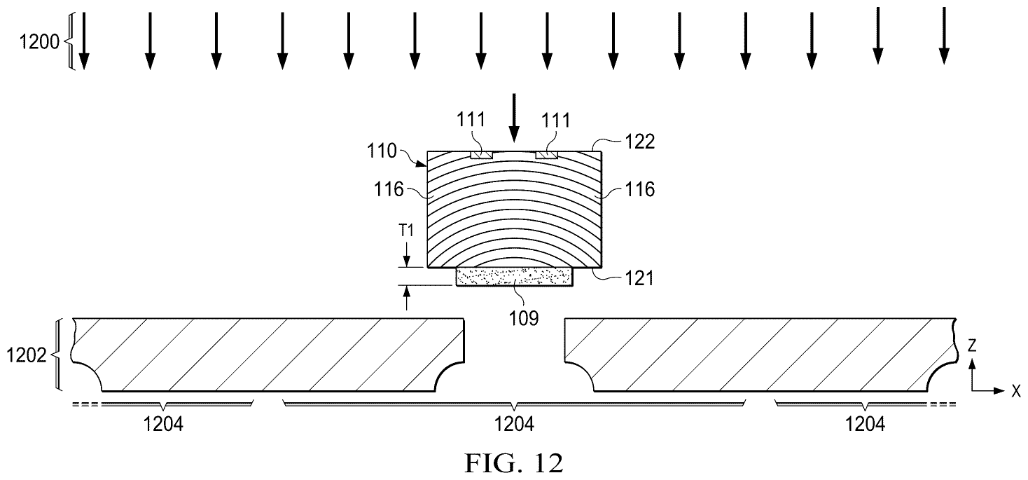

The method 200 continues at 218 in FIG. 2 with removal of the semiconductor die assemblies from the carrier. FIG. 11 shows one example, in which a die assembly removal process 1100 is performed that selectively removes the individual die assemblies including the separated semiconductor die 110 and the attached patterned portion of the non-conductive die attach film 109 from the carrier tape 302. The die assemblies can be stored for later attachment to a lead frame during subsequent electronic device packaging operations, or a single operation can remove the separated die assemblies from the carrier tape 302 for automated translation and placement on a lead frame panel array in a single operation.

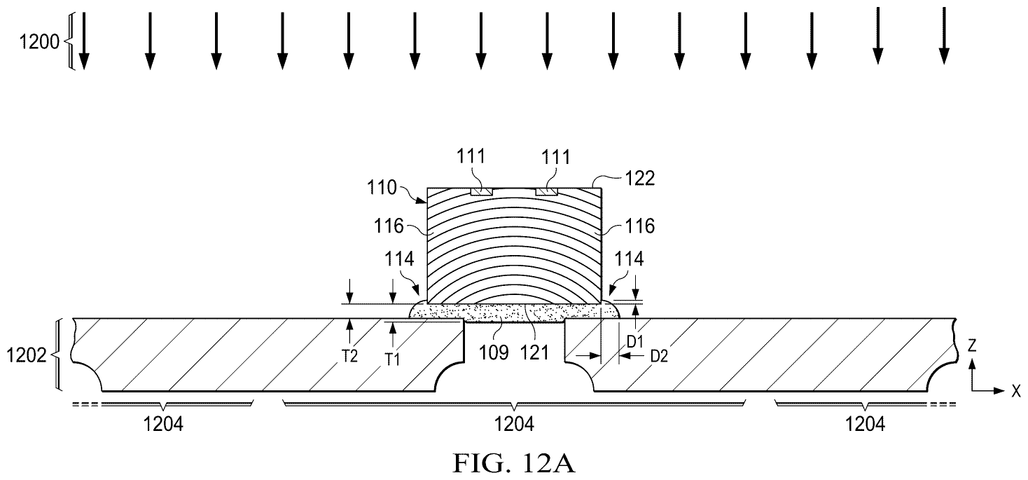

The method continues at 220 in FIG. 2 with die attach processing. FIGS. 12 and 12A illustrate one example, in which a die attach process 1200 is performed (e.g., using automated pick and place equipment, not shown) using a lead frame panel array 1202. The lead frame panel array 1202 in one example has rows and columns of unit areas 1204 disposed in rows and columns of a panel array structure, a portion of which is shown in FIGS. 12 and 12A. In one example, the process 1200 positions individual semiconductor die assemblies in corresponding unit areas 1204 of the array structure, with automated placement in first and second (e.g., X and Y) directions, and then translates the die assembly downward in the direction of the arrow in FIGS. 12 and 12A (e.g., along the third direction Z).

As shown in FIG. 12, the patterned non-conductive die attach film portion 109 has an initial first thickness T1 along the third direction Z (e.g., controlled by the deposition or lamination or other die attach film formation process used at 202 in FIG. 2) prior to attachment to the lead frame panel array 1202. As shown in FIG. 12A, the attachment process 1200 in one example includes applying a downward force to a singulated semiconductor die 110 while attaching the singulated portion of the non-conductive die attach film 109 to one or more prospective conductive leads 107 of the lead frame 1202. In certain implementations, the applied downward force helps to compress the singulated portion of the non-conductive die attach film 109 that engages the top side of the lead or leads to a smaller second thickness T2. In addition, the applied downward force during the die attach process 1200 in one example extends a portion of the singulated portion of the non-conductive die attach film 109 on a portion of one or more of the lateral sides (e.g., 123-126 above) of the singulated semiconductor die 110, including corner portions 114 shown in FIG. 12A, which extend above the plane of the bottom side 121 of the semiconductor die 110 by a non-zero distance D1 as discussed above in connection with FIGS. 1 and 1A.

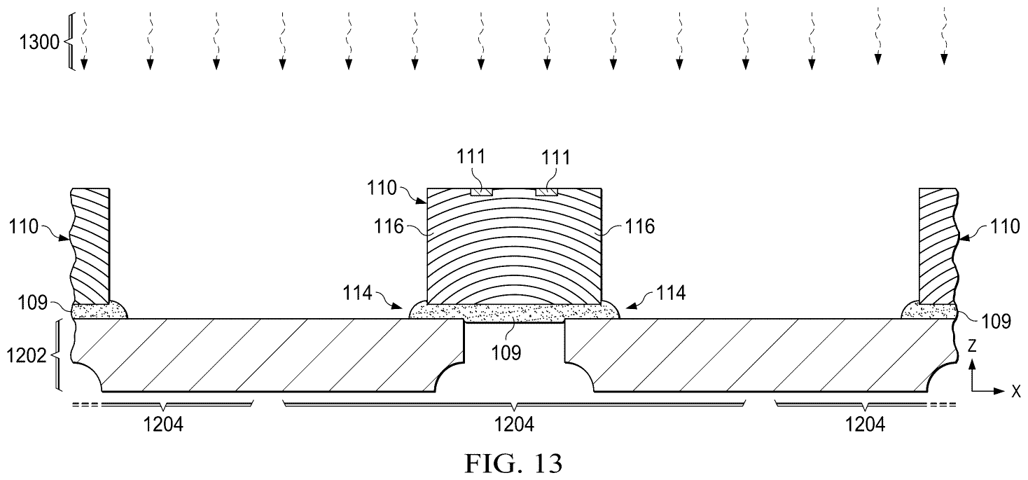

In one example, the method 200 includes die attach curing at 222 in FIG. 2. FIG. 13 shows one example, in which a thermal curing process 1300 is performed that cures the die attach film 109 to promote adhesion of the die attach film 109 and the associated semiconductor dies 110 to the conductive features (e.g., prospective leads) of the lead frame panel array 1202. In another implementation, the thermal curing process at 222 can be omitted.

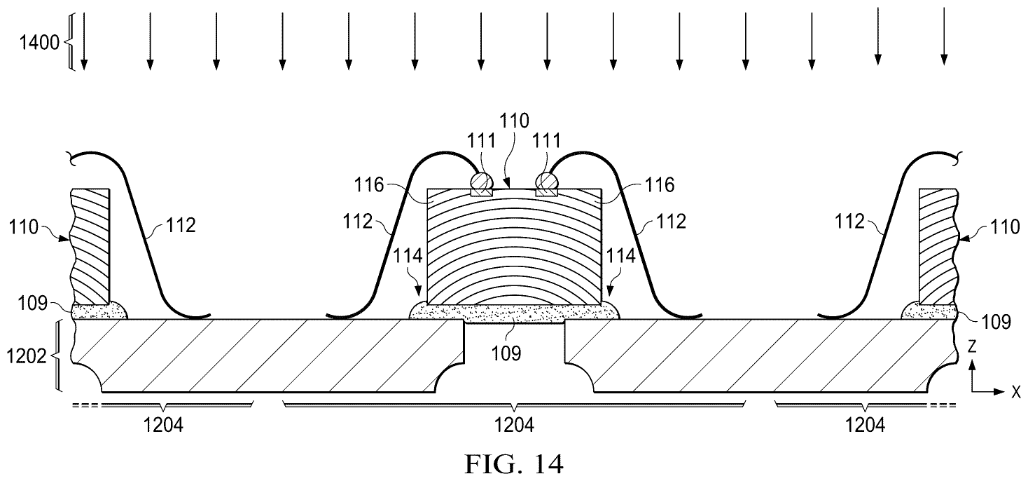

The method 200 continues at 224 in FIG. 2 with electrical connection processing to form one or more electrical connections between a circuit and/or component of the individual attached semiconductor dies 110 and prospective leads of the lead frame panel array 1202. FIG. 14 shows one example, in which a wire bonding process 1400 is performed that forms the bond wires 112 between respective ones of the conductive features 111 (e.g., bond pads) of the semiconductor die 110 and one of the prospective lead portions of the lead frame panel array 1202 in each of the unit areas 1204 of the array structure. In other implementations, other types and forms of electrical connection processing can be performed, for example, using conductive metal clips, flip-chip electrical interconnections (not shown) alone or in combination with wire bonding.

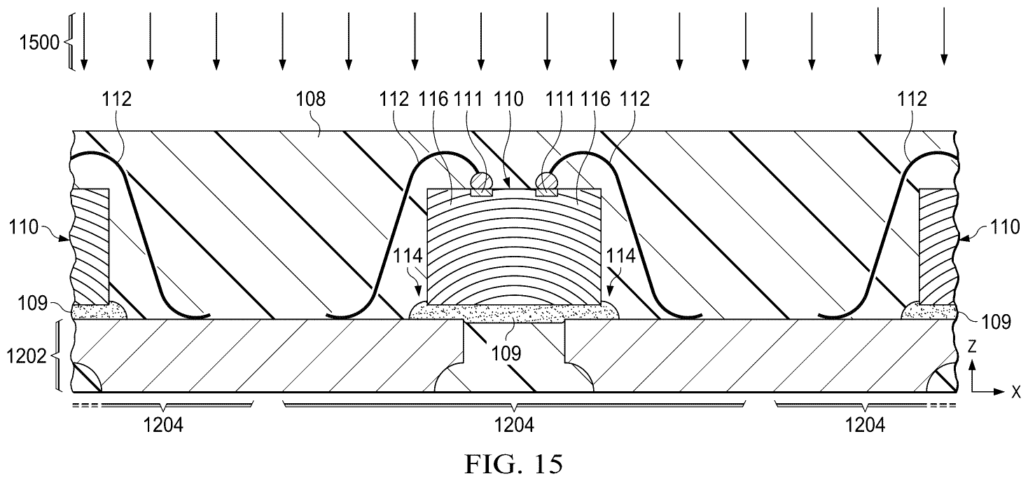

The method 200 continues at 226 in FIG. 2 with package formation. FIG. 15 shows one example, in which a molding process 1500 is performed using suitable mold structures (not shown) to form the package structure 108 that encloses the semiconductor dies 110, the bond wires 112, the die attach film portions 109, and upper portions of the prospective conductive lead features of the lead frame panel array 1202. In one example, a single mold cavity can be used to create a unitary molded package structure 108 that extends across multiple rows and/or columns of the lead frame panel array structure. In other implementations, separate die cavities can be used (not shown), for example, to create molded package structures 108 that are individually associated with a corresponding one of the unit areas 1204, or multiple mold cavities can be used that extend across multiple unit areas (e.g., rows or columns) of the array structure.

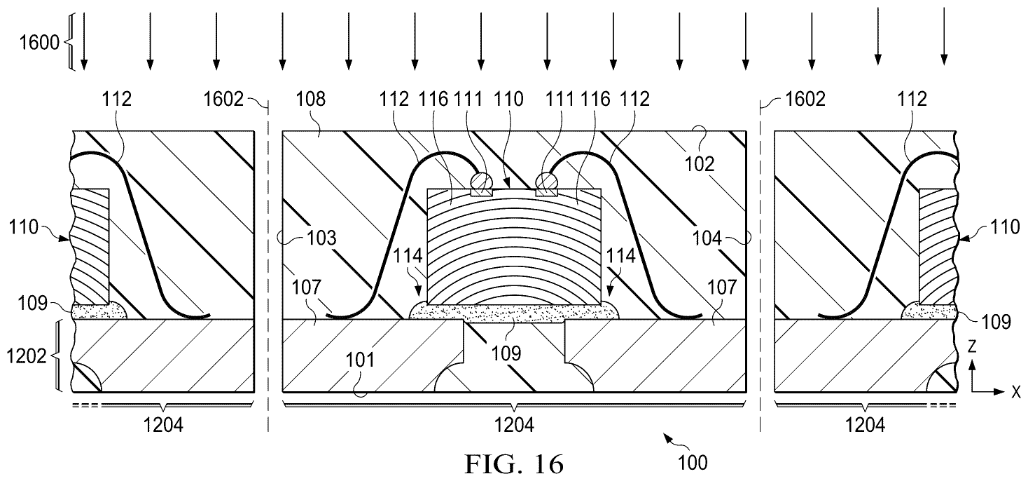

The method 200 in FIG. 2 continues at 228 with package separation processing. FIG. 16 shows one example, in which a package separation process 1600 is performed that separates individual finished packaged electronic devices 100 from one another and from the starting lead frame panel array structure. The illustrated example separates the individual packages and the conductive metal features of the lead frame along separation line 1602, for example, along rows and columns between adjacent unit areas 1204 of the array structure. Any suitable separation process 1600 can be used, for example, saw cutting, laser cutting, chemical etching, etc. or combinations thereof. The separation process 1600 cuts through certain portions of the starting lead frame structure, and creates approximately planar lateral sides (e.g., 103-106) of the electronic devices 100 including sides of the package structure 108 and the conductive metal leads 107 as shown in FIGS. 1, 1A and 16.

The described techniques and devices facilitate package size reduction, for example, in chip on lead packaged electronic devices that need not have a dedicated die attach pad as part of a lead frame, and a semiconductor die 110 is attached directly on one or more leads 107. The described examples help mitigate or avoid creation of silicon particles embedded within a dic attach film, and thus facilitate electrical isolation between the attached semiconductor die 110 and conductive metal leads 107 of the finished packaged electronic device 100, which allows use of conductive metal leads both for supporting an attached semiconductor die 110 and carrying signals that can have voltages different from a voltage of the silicon of the semiconductor die 110 during operation when installed in a host system (e.g., FIG. 1 above).

The above examples are merely illustrative of several possible implementations of various aspects of the present disclosure, wherein equivalent alterations and/or modifications will occur to others skilled in the art upon reading and understanding this specification and the annexed drawings. Modifications are possible in the described examples, and other implementations are possible, within the scope of the claims.

What is claimed is:

1. An electronic device, comprising:
a conductive lead;
a non-conductive die attach film on a side of the conductive lead;
a semiconductor die having a first side and a lateral side, the first side on the non-conductive die attach film, and the lateral side including striations; and
a package structure enclosing the semiconductor die and a portion of the conductive lead.

2. The electronic device of claim 1, wherein the semiconductor die has a conductive feature along a second side that is opposite the first side, the conductive feature electrically connected to the conductive lead.

3. The electronic device of claim 1, further comprising a bond wire connected between the conductive lead and a conductive feature of the semiconductor die.

4. The electronic device of claim 1, wherein the non-conductive die attach film extends on a portion of the lateral side.

5. The electronic device of claim 4, wherein the non-conductive die attach film extends on portions of two opposite the lateral sides of the semiconductor die.

6. The electronic device of claim 1, further comprising a second conductive lead partially enclosed by the package structure, wherein the semiconductor die has a conductive feature along a second side that is opposite the first side, the conductive feature electrically connected to the second conductive lead.

7. The electronic device of claim 1, further comprising a second conductive lead partially enclosed by the package structure, wherein the non-conductive die attach film extends on a side of the second conductive lead.

8. A system, comprising:
a circuit board with a conductive feature; and
an electronic device, comprising:
a conductive lead connected to the conductive feature of the circuit board;
a non-conductive die attach film on a side of the conductive lead;
a semiconductor die having a first side and a lateral side, the first side on the non-conductive die attach film, and the lateral side including striations; and
a package structure enclosing the semiconductor die and a portion of the conductive lead.

9. The system of claim 8, wherein the semiconductor die has a conductive feature along a second side that is opposite the first side, the conductive feature electrically connected to the conductive lead.

10. The system of claim 8, the electronic device further comprising a bond wire connected between the conductive lead and a conductive feature of the semiconductor die.

11. The system of claim 8, wherein the non-conductive die attach film extends on a portion of the lateral side.

12. The system of claim 11, wherein the non-conductive die attach film extends on portions of two opposite the lateral sides of the semiconductor die.

13. The system of claim 8, the electronic device further comprising a second conductive lead partially enclosed by the package structure and connected to a second conductive feature of the circuit board, wherein the semiconductor die has a conductive feature along a second side that is opposite the first side, the conductive feature electrically connected to the second conductive lead.

14. The system of claim 8, the electronic device further comprising a second conductive lead partially enclosed by the package structure and connected to a second conductive feature of the circuit board, wherein the non-conductive die attach film extends on a side of the second conductive lead.

15. A method of fabricating an electronic device, the method comprising:
singulating portions of a non-conductive die attach film on a carrier;
attaching a backside of a wafer to the singulated portions of the non-conductive die attach film; and
singulating semiconductor dies of the wafer while the backside of the wafer is attached to the singulated portions of the non-conductive die attach film.

16. The method of claim 15, further comprising aligning prospective die areas of the wafer with respective singulated portions of the non-conductive die attach film before attaching the backside of a wafer to the singulated portions of the non-conductive die attach film.

17. The method of claim 16, wherein aligning prospective die areas of the wafer with respective singulated portions of the non-conductive die attach film includes optically aligning the wafer with respect to a pattern of the non-conductive die attach film on the carrier.

18. The method of claim 15, further comprising forming a patterned etch mask on a front side of the wafer before attaching the backside of a wafer to the singulated portions of the non-conductive die attach film, wherein singulating the dies of the wafer includes performing an etch process that separates the semiconductor dies from the wafer with backsides of the semiconductor dies attached to respective singulated portions of the non-conductive die attach film.

19. The method of claim 18, wherein the etch process is a plasma etch process.

20. The method of claim 15, wherein singulating the portions of the non-conductive die attach film includes performing a laser ablation process.

21. The method of claim 15, wherein singulating the portions of the non-conductive die attach film includes performing a mechanical cutting process.

22. The method of claim 15, further comprising applying a downward force to a singulated semiconductor die while attaching the singulated portion of the non-conductive die attach film of the singulated semiconductor die to a prospective conductive lead of a lead frame to compress the singulated portion of the non-conductive die attach film and extend a portion of the singulated portion of the non-conductive die attach film on a portion of a lateral side of the singulated semiconductor die.
